(19) United States
(12) Patent Application Publication
(10) Pub. No.: US 2026/0282711 A1
(43) Pub. Date: Sep. 17, 2026

(54) ELECTRONIC DEVICE

(71) Applicant: Samsung Display Co., LTD., Yongin-si (KR)

(72) Inventors: HYUNSANG PARK, Yongin-si (KR); ONOUE SHINYA, Yongin-si (KR); KYOUNGDUCK KIM, Yongin-si (KR); WOORAM SEO, Yongin-si (KR); JAE-YOUNG YU, Yongin-si (KR); JINYOUNG LEE, Yongin-si (KR); YONG SEONG JANG, Yongin-si, Gyeonggi-do (KR); SEUNGJIN LIM, Yongin-si (KR); WU HYEON JUNG, Yongin-si (KR)

(21) Appl. No.: 19/535,212

(22) Filed: Feb. 10, 2026

(30) Foreign Application Priority Data
Mar. 11, 2025 (KR) 10-2025-0031539
Nov. 19, 2025 (KR) 10-2025-0176267

(51) Int. Cl. H10K 59/80

(52) U.S. Cl. CPC H10K 59/873

(57) ABSTRACT

An electronic device is provided which includes a display panel including light emitting pixels, a first protective layer positioned on a rear surface of the display panel, and a first adhesive layer positioned between the display panel and the first protective layer, wherein the first adhesive layer includes a non-conductive film (NCF).

This application claims priority to Korean Patent Application Nos. 10-2025-0031539 and 10-2025-0176267, filed on Mar. 11, 2025, and Nov. 19, 2025, respectively, and all the benefits accruing therefrom under 35 U.S.C. § 119, the content of which in its entirety is herein incorporated by reference.

### BACKGROUND

### 1. Field

The present disclosure relates to an electronic device.

### 2. Description of the Related Art

Electronic devices can be activated according to electrical signals and may include a display device which displays images. The display device may include light emitting diodes, and the light emitting diodes can implement deep and vivid colors and provide a wide viewing angle.

In some cases, a display device included in the electronic device may include a curved area where each side and corner portion is bent at a predetermined angle. A display device including such a curved area may enhance user convenience and provide a wide viewing angle.

### SUMMARY

Embodiments may provide an electronic device capable of solving buckling which may occur in a curved area of the display device.

An electronic device according to an embodiment includes a display panel including light emitting pixels, a first protective layer positioned on a rear surface of the display panel, and a first adhesive layer positioned between the display panel and the first protective layer, wherein the first adhesive layer includes a non-conductive film (NCF).

A modulus of the first adhesive layer may be 20 MPa or greater.

An adhesive strength of the first adhesive layer may be 2800 gf/in or greater.

The first protective layer comprises metal or glass.

The first protective layer is in direct contact with the first adhesive layer.

The electronic device may further include a second protective layer positioned on a front surface of the display panel opposite to the rear surface.

The electronic device may further include a second adhesive layer positioned between the display panel and the second protective layer.

The adhesive strength of the first adhesive layer may be greater than the adhesive strength of the second adhesive layer.

The display panel may include a planar area and a curved area bent at a corner portion of the display panel, and a display panel bending angle at which the display panel is bent in the curved area ranges from 45° to 85°.

The non-conductive film may include epoxy, polyacrylate or urethane.

The electronic device may further include a support plate positioned on a rear surface of the first protective layer.

An electronic device according to an embodiment includes a display panel including light emitting pixels, a first protective layer positioned on a rear surface of the display panel, a support plate positioned on a rear surface of the first protective layer, and three or more adhesive layers, wherein a third adhesive layer of the three or more adhesive layers is positioned between the first protective layer and the support plate, and the third adhesive layer includes a non-conductive film (NCF).

A modulus of the third adhesive layer may be 20 MPa or greater.

An adhesive strength of the third adhesive layer may be 2800 gf/in or greater.

The first protective layer is in direct contact with the third adhesive layer.

The electronic device may further include a second protective layer positioned on a front surface of the display panel opposite to the rear surface.

The electronic device may further include a second adhesive layer positioned between the display panel and the second protective layer.

The adhesive strength of the third adhesive layer may be greater than the adhesive strength of the second adhesive layer.

The display panel may include a planar area and a curved area bent at a corner portion of the display panel, and a display panel bending angle at which the display panel is bent in the curved area may range from 45° to 85°.

The non-conductive film may include epoxy or polyacrylate.

The electronic device may further include a first adhesive layer positioned between the display panel and the first protective layer.

The first adhesive layer may include a pressure sensitive adhesive.

According to the embodiments, buckling which may occur at a corner portion of the electronic device may be prevented.

Further, according to the embodiments, there are advantageous effects which may be recognized throughout the specification.

### BRIEF DESCRIPTION OF THE DRAWINGS

FIG. 1 is a perspective view illustrating an electronic device according to an embodiment.

FIG. 2 is an exploded perspective view illustrating a portion of an electronic device according to an embodiment.

FIG. 3 is a view illustrating a stacked structure of a display device included in an electronic device according to an embodiment.

FIG. 4 is a diagram illustrating first to third layers of the first protective layer.

FIG. 5 is a cross-sectional view taken along line V-V′ of FIG. 1.

FIGS. 6 and 7 are views for explaining refraction and distortion of light according to surface waviness.

FIG. 8 is an equivalent circuit diagram of any one pixel circuit included in the display panel.

FIG. 9 is a cross-sectional view illustrating a portion of a display panel provided in the electronic device.

FIG. 10 is a view illustrating a stacked structure of a display device included in an electronic device according to an embodiment.

FIG. 11 is simulation data illustrating interface pressure differences according to materials of an adhesive layer.

FIG. 12 is a block diagram of an electronic device according to an embodiment.

### DETAILED DESCRIPTION

Hereinafter, various embodiments of the present disclosure will be described in detail with reference to the accompanying drawings such that those skilled in the art to which the present disclosure pertains can easily implement them. The present disclosure may be implemented in various different forms and is not limited to the embodiments described herein.

To clearly explain the present disclosure, parts irrelevant to the description have been omitted, and the same reference signs are assigned to the same or similar components throughout the specification.

Terms such as, for example, first, second, and the like may be used to describe various components, but the components should not be limited by the terms. The terms as used herein may distinguish one component from other components and are not to be limited by the terms. For example, without departing the scope of the present disclosure, a first component may be referred to as a second component, and similarly, the second component may also be referred to as the first component. The terms of a singular form may include plural forms unless otherwise specified.

The terminology used herein is for the purpose of describing particular embodiments and is not intended to be limiting. As used herein, “a,” “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items.

It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, or components.

The terms “about” or “approximately” as used herein are inclusive of the stated value and include a suitable range of deviation for the particular value as determined by one of ordinary skill in the art, considering the measurement in question and the error associated with measurement of the particular quantity. The term “about” can mean within one or more standard deviations, or within ±30%, 20%, 10%, 5% of the stated value, for example.

The term “substantially,” as used herein, means approximately or actually. The term “substantially equal” means approximately or actually equal. The term “substantially the same” means approximately or actually the same. The term “substantially identical” means approximately or actually identical. The term “substantially perpendicular” means approximately or actually perpendicular.

The size and thickness of each component illustrated in the drawings are arbitrarily illustrated for convenience of explanation, so the present disclosure is not necessarily limited to what is illustrated. The thickness is enlarged to clearly represent various layers and regions in the drawings. And in the drawings, for convenience of explanation, the thickness of some layers and regions is exaggerated.

For cases in which a part such as a layer, film, region, plate, and the like is said to be “on” or “over” another part, this includes not only the case where it is “directly on” the other part, but also the case where there is another part in between. Conversely, descriptions that a part is said to be “directly on” another part mean that there is no other part in between. Being “on” or “over” a reference part means being positioned above or below the reference part, and does not necessarily mean being positioned “on” or “over” in the direction opposite to gravity.

Throughout the specification, descriptions that a part “includes” a certain component means that other components may be further included rather than excluding other components unless otherwise stated.

Throughout the specification, “in a plan view” refers to a case in which the target part is viewed from above, and “in cross-section” refers to a case in which a cross-section of the target part cut vertically is viewed from the side.

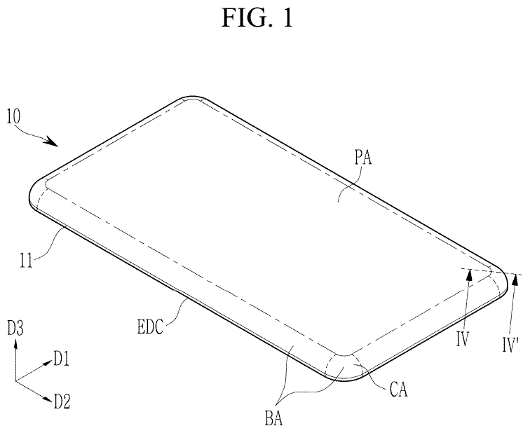

Hereinafter, an electronic device according to an embodiment will be described with reference to FIG. 1. FIG. 1 is a perspective view illustrating an electronic device according to an embodiment.

The electronic device 10 may be a device which performs various tasks using electricity. The electronic device 10 may have a function of transmitting, storing, and computing information by processing or converting electrical signals. The electronic device 10 including the display panel may perform a function of providing visual information. The electronic device 10 including the display panel may include smartphones, cameras, tablets, notebook computers, monitors, televisions, smart watches, e-book readers, PDAs (personal digital assistants), PMPs (portable multimedia players), game consoles, and automotive navigation systems.

The electronic device 10 may have a substantially rectangular shape in a plan view. The electronic device 10 may include both short sides extending in a first direction D1 and both long sides extending in a second direction D2 intersecting the first direction D1 in the plan view. A corner portion CA where the long side and the short side meet may have a curved shape in the plan view.

The long side and the short side of the electronic device 10 may be bent in a third direction D3 which intersects the first direction D1 and the second direction D2, respectively. In some aspects, the corner portion CA of the electronic device 10 may be bent in the third direction D3. The corner portion CA may be disposed between a curved area BA disposed along the long side and a curved area BA disposed along the short side. The electronic device 10 according to an embodiment may include four corner portions CA. The curved area BA may include long sides, short sides, and corner portions CA which are bent in the third direction D3. The curved area BA may surround a planar area PA which is a flat surface of the electronic device 10.

The electronic device 10 may display an image toward the third direction D3 in the planar area PA. In some aspects, the electronic device 10 may display an image toward a normal direction of the curved surface in the curved area BA. The normal direction of the curved surface may be a direction perpendicular to a tangent line of the curve. The image may include dynamic images as well as still images.

The electronic device 10 may include a display device 11 and a case EDC. The case EDC may include a material having relatively high rigidity. For example, the case EDC may include glass, plastic, or metal, or may include a frame composed of a combination thereof. The case EDC may absorb impacts applied from the outside or prevent foreign substances/moisture from penetrating from the outside to protect the display device accommodated in the case EDC.

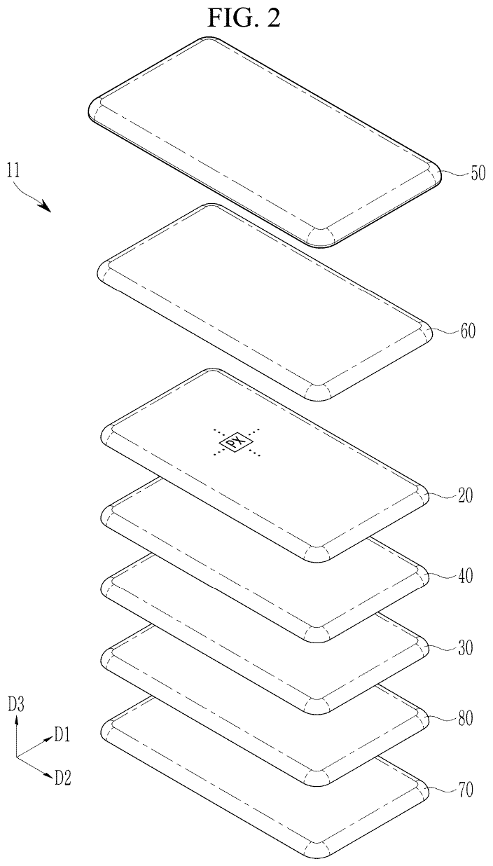

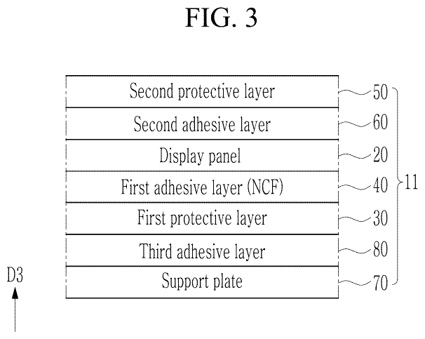

Hereinafter, a display device will be described in more detail with reference to FIGS. 2 to 3. FIG. 2 is an exploded perspective view illustrating a portion of an electronic device according to an embodiment, and FIG. 3 is a view illustrating a stacked structure of a display device included in an electronic device according to an embodiment. Description of components identical to the aforementioned components will be omitted.

An electronic device according to an embodiment may include a display device 11.

The display device 11 may include a display panel 20, a first protective layer 30, a first adhesive layer 40, a second protective layer 50, a second adhesive layer 60, a support plate 70, and a third adhesive layer 80. The display device 11 may have a support plate 70, a third adhesive layer 80, a first protective layer 30, a first adhesive layer 40, a display panel 20, a second adhesive layer 60, and a second protective layer 50 sequentially stacked along the third direction D3. If desirable, the display device 11 may further include other layers in addition to these.

Hereinafter, a front surface of each layer of the display device 11 may mean an upper surface and a rear surface may mean a lower surface. The upper surface and the lower surface may be opposite to each other.

The display panel 20 may include a plurality of light emitting pixels PX. The display panel 20 may be a device for visually displaying information on a screen. The light emitting pixel PX may include a light emitting element capable of emitting light. The light emitting pixels PX may include red pixels, green pixels, and blue pixels. The red pixel may emit red light, the green pixel may emit green light, and the blue pixel may emit blue light. However, embodiments of the present disclosure are not limited thereto, and the light emitting pixels PX may include pixels which emit white light. In some aspects, various colors for implementing a screen may be emitted.

Although not illustrated in FIG. 3, the display device 11 may include a flexible printed circuit board (FPCB) which extends from one surface of an end portion of the display panel 20 and is attached to an end portion of one surface of the support plate 70. In other words, the FPCB is a flexible circuit board which may be attached to a front surface of the display panel 20 and the rear surface of the display device 11. Specifically, the FPCB may be attached to the front surface of the display panel 20 and a rear surface of the support plate 70.

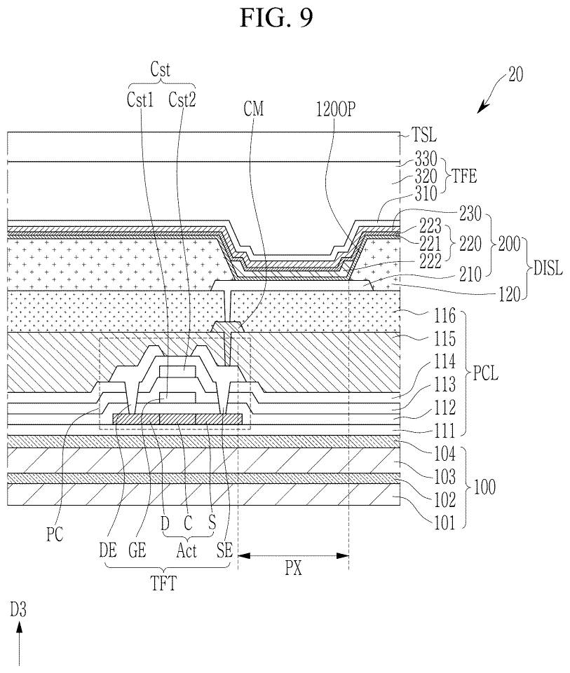

A specific structure of the display panel 20 will be described in detail with reference to FIG. 9.

The first protective layer 30 may be positioned on a rear surface of the display panel 20. The first protective layer 30 may act as a cushion for absorbing impacts from the outside of the display device to prevent damage to the rear surface of the display panel 20. In some aspects, the first protective layer 30 may have a dark color (e.g., black) applied to help with background display for cases in which the screen is off.

The first protective layer 30 may include a polymer member. For example, the first protective layer 30 may include polyethylene terephthalate (PET) or polyimide (PI). Also, the first protective layer 30 may include metal. For example, the first protective layer 30 may include pure titanium (Pure Ti), titanium alloy (Ti alloy), stainless steel, aluminum alloy (Al alloy), copper (Cu), nickel alloy (Ni alloy), and the like. Also, the first protective layer 30 may include clad metal. Clad metal may be an integrated or single composite material in which a plurality of metals are laminated. Clad metal may be manufactured through various methods such as welding, pressing, casting, extruding, or laser cladding of the plurality of metals. For example, clad metal may be Ni-Cu-Ni or phosphor bronze-Cu-phosphor bronze. Also, the first protective layer 30 may include glass. By the first protective layer 30 including metal or glass, the overall modulus of the display device included in the electronic device according to an embodiment may be improved, which may be advantageous in preventing buckling that may occur at a corner portion of the display panel 20.

A first adhesive layer 40 may be positioned between the display panel 20 and the first protective layer 30. The first adhesive layer 40 may bond the display panel 20 and the first protective layer 30. The first protective layer 30 may be in direct contact with the first adhesive layer 40

The first adhesive layer 40 may include a non-conductive film (NCF). The non-conductive film may be an adhesive film to which an underfill function is added. The non-conductive film may perform an underfill role at an interface where two layers are in contact with each other. With this, stress and deformation caused by a difference in thermal expansion coefficient between the two layers may be redistributed and alleviated. The non-conductive film is a film which does not have electrical conductivity and may block electrical flow. The first adhesive layer 40 including the non-conductive film may minimize electrical interference with the display panel 20. In some aspects, because the non-conductive film has excellent thermal stability, the non-conductive film may maintain insulation performance even at high temperatures. In some aspects, because the non-conductive film is thin and has high mechanical strength, the non-conductive film may perform a role of protecting electronic components from external impact or mechanical damage.

The non-conductive film may include a matrix polymer and a cross-linking agent dispersed in the matrix polymer. The non-conductive film may exhibit adhesiveness through a crosslinking reaction between the matrix polymer and the curing agent via various curing mechanisms such as heating, light irradiation, or humidity exposure. In particular, thermosetting polymers undergo crosslinking reactions upon heating, photocurable polymers undergo crosslinking reactions induced by ultraviolet irradiation, and thermoplastic polymers achieve melt adhesion through heating. The matrix polymer may be, for example, bisphenol A-type epoxy resin, bisphenol F-type epoxy resin, naphthalene-type epoxy resin, aminophenol-type epoxy resin, hydrogenated bisphenol-type epoxy resin, cycloaliphatic epoxy resin, alcohol ether-type epoxy resin, cycloaliphatic-type epoxy resin, fluorene-type epoxy resin, siloxane-based epoxy resin. Also, the matrix polymer may be polyacrylate. Also, the matrix polymer may be urethane such as polyether polyurethane, polyester polyurethane, polycarbonate polyurethane, polyol-based polyurethane, and the like. However, the matrix polymer is not limited thereto. These may be used alone or in combination of two or more. The curing agent may be, for example, acid anhydride-based curing agents such as, for example, tetrahydrophthalic anhydride, methyltetrahydrophthalic anhydride, methylhexahydrophthalic anhydride, hexahydrophthalic anhydride, trialkyltetrahydrophthalic anhydride, methylcyclohexenedicarboxylic anhydride, phthalic anhydride, maleic anhydride, pyromellitic anhydride; aromatic amine-based curing agents such as, for example, metaphenylenediamine, diaminodiphenylmethane, diaminodiphenylsulfone; aliphatic amine-based curing agents such as, for example, diethylenetriamine, triethylenetetramine; phenolic curing agents such as, for example, phenol aralkyl type phenol resins, phenol novolac type phenol resins, xyloc type phenol resins, cresol novolac type phenol resins, naphthol type phenol resins, terpene type phenol resins, polyfunctional phenol resins, dicyclopentadiene-based phenol resins, naphthalene type phenol resins, novolac type phenol resins synthesized from bisphenol A and resol; latent curing agents such as, for example, dicyandiamide, but are not limited thereto. These may be used alone or in combination of two or more.

In particular, the non-conductive film may be easily formed to have high values of adhesive strength and modulus. Adhesive strength may be a force by which two objects stick to each other. The stronger the adhesive strength, the stronger the two objects may be bonded. Modulus may be a ratio of stress to deformation which an elastic body has in an elastic limit. An object with a high modulus may be less deformed against external forces.

Because the first adhesive layer 40 includes the non-conductive film, electrical interference with the display panel 20 may be minimized. In some aspects, including the non-conductive film in the first adhesive layer 40 supports widely adjusting the adhesive strength and modulus of the first adhesive layer 40. Accordingly, the first adhesive layer 40 may prevent buckling from occurring at the corner portion of the display panel 20.

The second protective layer 50 may be positioned on a front surface of the display panel 20. The front surface of the display panel 20 may be opposite to the rear surface of the display panel 20. The front surface of the second protective layer 50 may correspond to the front surface of the electronic device 10. The second protective layer 50 may cover the entire upper surface of the display device 11. The second protective layer 50 may correspond to the shape of the display device 11. The second protective layer 50 may mitigate external impacts to prevent the display device 11 from being damaged or malfunctioning due to external impacts.

The second protective layer 50 may include an optically transparent material. The second protective layer 50 may include an optically transparent substrate. For example, the second protective layer 50 may include a glass substrate, and the glass substrate may be a tempered glass substrate.

A second adhesive layer 60 may be positioned between the display panel 20 and the second protective layer 50. The second adhesive layer 60 may bond the display panel 20 and the second protective layer 50.

The second adhesive layer 60 may include at least one of an optically clear adhesive (OCA), an optically clear resin (OCR), a pressure sensitive adhesive (PSA), a thermally reactive adhesive, or a double-sided tape.

The adhesive strength of the first adhesive layer 40 may be greater than the adhesive strength of the second adhesive layer 60.

The support plate 70 may be positioned on a rear surface of the first protective layer 30. The support plate 70 may help to reinforce the rigidity of the electronic device, shield surrounding noise, and may be used to dissipate heat emitted from surrounding heat-emitting components.

The support plate 70 may include metal. As an example, the support plate 70 may include at least one of stainless steel, Cu, Al, or clad metal (e.g., a laminated member in which stainless steel and aluminum are alternately arranged). In some aspects, the support plate 70 may include other alloy materials.

The support plate 70 may include at least one reinforced fiber composite according to the embodiment. For example, the support plate 70 may include at least one of carbon fiber reinforced plastic (CFRP) and glass fiber reinforced plastic (GFRP).

A third adhesive layer 80 may be positioned between the first protective layer 30 and the support plate 70. The third adhesive layer 80 may bond the first protective layer 30 and the support plate 70.

The third adhesive layer 80 may include at least one of an optically clear adhesive, an optically clear resin, a pressure sensitive adhesive, a thermally reactive adhesive, or a double-sided tape.

In some aspects, the adhesive strength of the first adhesive layer 40 may be greater than the adhesive strength of the third adhesive layer 80.

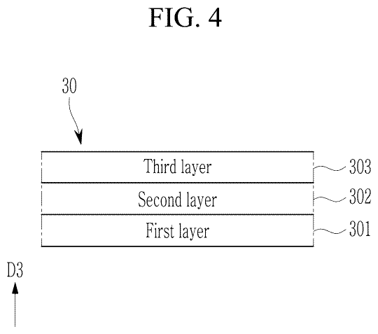

Hereinafter, with reference to FIG. 4, a case where the first protective layer includes clad metal will be described. FIG. 4 is a diagram illustrating first to third layers of the first protective layer.

The first protective layer 30 may include clad metal. When the first protective layer 30 includes clad metal, the first protective layer 30 may have a multilayered structure. FIG. 4 is a diagram illustrating the first protective layer 30 including clad metal.

When the first protective layer 30 includes clad metal, the first protective layer 30 may include a first layer 301, a second layer 302, and a third layer 303. The first layer 301, the second layer 302, and the third layer 303 may be stacked in order. That is, the second layer 302 may be positioned between the first layer 301 and the third layer 303.

For example, the clad metal included in the first protective layer 30 may be Ni—Cu—Ni. In other words, the first layer 301 may include nickel, the second layer 302 may include copper, and the third layer 303 may include nickel.

Also, the clad metal included in the first protective layer 30 may be phosphor bronze-Cu-phosphor bronze. In other words, the first layer 301 may include phosphor bronze, the second layer 302 may include copper, and the third layer 303 may include phosphor bronze.

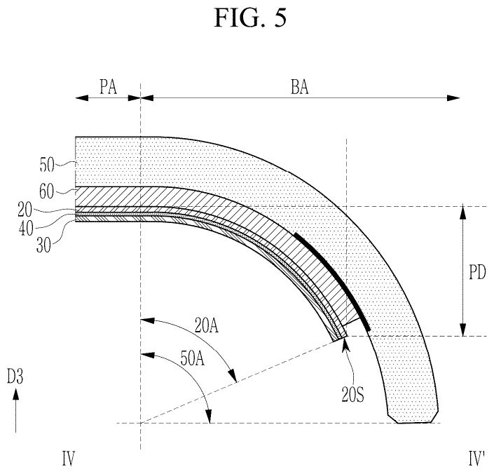

Hereinafter, the curved area will be described in more detail with reference to FIG. 5. FIG. 5 is a cross-sectional view taken along line V-V′ of FIG. 1. FIG. 5 illustrates a portion of the display panel 20, the first adhesive layer 40, the second protective layer 50, the second adhesive layer 60, and the first protective layer 30 stacked at the corner portion of the electronic device.

In the curved area BA, the second protective layer 50 may cover the display panel 20, the first adhesive layer 40, the second adhesive layer 60, and the first protective layer 30. The second protective layer 50 may be formed in a wider area than the display panel 20, the first adhesive layer 40, the second adhesive layer 60, and the first protective layer 30.

In the curved area BA, the second protective layer 50 may be bent by a protective layer bending angle 50A. By having the second protective layer 50 have a sufficiently large protective layer bending angle 50A, the display panel 20 may be easily protected. For example, the protective layer bending angle 50A may be 80° to 90°.

The display panel 20 may be positioned on a rear surface of the second protective layer 50. The display panel 20 may include a planar area PA and a curved area BA. The display panel 20 may be bent toward the third direction D3 in the curved area BA. In the curved area BA, the display panel 20 may have a display panel bending angle 20A. The protective layer bending angle 50A may be greater than the display panel bending angle 20A. The display panel bending angle may range from 45° to 85°.

The display panel depth PD may be a length of the display panel 20 in the third direction D3 in the curved area BA. The display panel depth PD may be a value obtained by measuring a length of the display panel 20 positioned in the curved area BA in the third direction D3 based on the display panel 20 positioned in the planar area PA.

The bezel of the electronic device may be minimized by making the display panel depth PD at the corner portion of the electronic device sufficiently large. This is because as the display panel depth PD becomes longer, the length of the display panel 20 extending in the curved area BA may become longer. Conversely, as the display panel depth PD becomes shorter, the length of the display panel 20 extending in the curved area BA becomes shorter, so the bezel may become larger. To make the display panel depth PD sufficiently large, the display panel bending angle 20A also needs to be increased.

However, for a case in which the display panel bending angle 20A increases, defects may occur in the display device. This may be because each layer of the display device has a curvature difference at the corner portion including the curved area BA. As the display panel bending angle 20A increases, buckling may occur in the stress portion 20S of the display panel 20. The buckling of the display panel 20 may be a phenomenon in which the display panel 20 is abnormally deformed by external pressure or load. At the corner portion of the electronic device, the display panel 20 may be stacked while being compressed inside the second protective layer 50. At this time, for a case in which a load exceeding a critical load is applied, the display panel 20 may partially undergo tension or contraction. A portion where contraction is concentrated may be referred to as a stress portion 20S of the display panel 20. The stress portion 20S of the display panel 20 may be positioned at an end portion of the display panel 20. For a case in which buckling occurs in the display panel 20, structural stability of the display device may be damaged. In some aspects, the function and quality of the display panel 20 may be degraded or the display panel 20 may be damaged.

To prevent buckling of the display panel 20 which may occur as the display panel bending angle 20A is increased to minimize the bezel, a non-conductive film may be included in the first adhesive layer 40. The first adhesive layer 40 including the non-conductive film may be positioned between the display panel 20 and the first protective layer 30. The first adhesive layer 40 including the non-conductive film may support the display panel 20 by being positioned on the rear surface of the display panel 20.

The first adhesive layer 40 including the non-conductive film may provide high adhesive strength and high modulus.

The non-conductive film may achieve higher modulus through a specific curing process while maintaining structural strength. For example, pressure sensitive adhesives basically have flexible and adhesive high elastic characteristics in many cases, so it may be difficult to obtain high modulus. However, for example, a non-conductive film including epoxy may be adjusted to a stronger and harder material by further including a curing agent or a filler. Therefore, the non-conductive film may be easily manufactured to have a relatively high modulus compared to the pressure sensitive adhesive. For example, the modulus of the first adhesive layer 40 including the non-conductive film may be 20 MPa or greater. The higher the modulus, the greater the resistance to deformation against external force, so reliability against shape deformation may be improved.

In some aspects, the non-conductive film may be easily manufactured to have relatively high adhesive strength compared to the pressure sensitive adhesive. For example, the non-conductive film may be manufactured to have an adhesive strength which is about 5 times or higher than an adhesive strength of the pressure sensitive adhesive. For example, the adhesive strength of the first adhesive layer 40 may be 2800 gf/in or greater. The higher the adhesive strength, the better the prevention of interfacial delamination.

By positioning the first adhesive layer 40 including the non-conductive film on the rear surface of the display panel 20, buckling which may occur in the display device 11 may be prevented. Because the first adhesive layer 40 including the non-conductive film structurally and stably supports the display panel 20, even if contraction is concentrated in the stress portion 20S of the display panel 20, buckling may not occur in the display panel 20. In some aspects, because the first adhesive layer 40 including the non-conductive film is strongly bonded to the display panel 20, delamination of the display panel 20 and the first adhesive layer 40 may be prevented, and the display panel 20 may be continuously and stably supported.

The display device including the display panel 20, the first protective layer 30, the first adhesive layer 40, the second protective layer 50, and the second adhesive layer 60 may be stacked in a flat shape. The display device immediately after the stacking is completed has a flat shape and may not include a curved area.

A curing and molding device may be used to form the curved area. The curing and molding device may compress the display device by pressing it from above and below. The curing and molding device may cure the first adhesive layer by applying heat to the display device. In some aspects, the curing and molding device may mold each side and corner portion of the display device to be curved. In other words, the curing and molding device may form the curved area BA in the display device.

The curved area BA of the display device may be formed to reduce a bezel size of the electronic device. The curing and molding device may form the curved area BA of the display device while compressing the display device.

The first adhesive layer 40 including the non-conductive film may be cured by receiving heat from the curing and molding device. In other words, the first adhesive layer 40 including the non-conductive film may have increased modulus by receiving heat from the curing and molding device. The first adhesive layer 40 having increased modulus may prevent buckling occurring in the display panel 20. Curing and molding of the display device may be performed simultaneously.

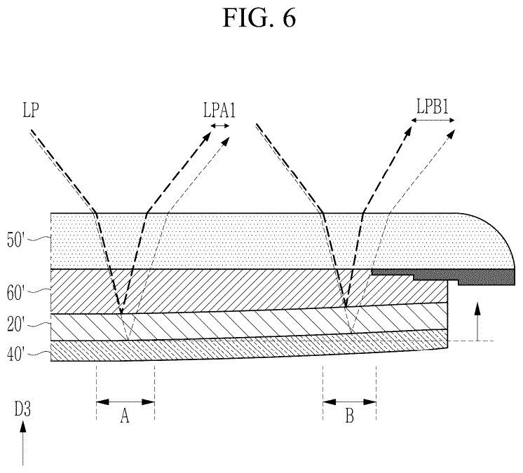

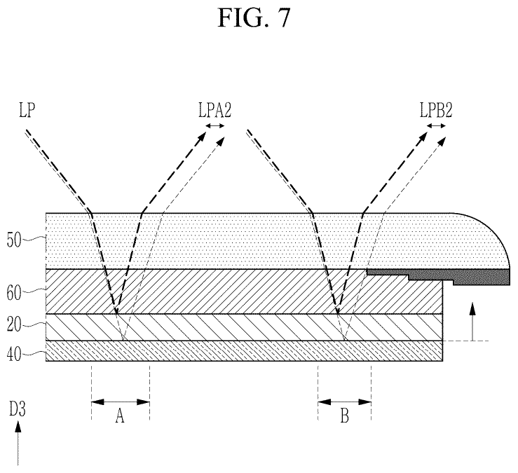

The first adhesive layer 40 including the non-conductive film may compensate for refraction and distortion which may occur due to light introduced from the outside. This will be described with reference to FIGS. 6 and 7. FIGS. 6 and 7 are views for explaining refraction and distortion of light according to surface waviness.

FIG. 6 illustrates a display device in which a display panel 20′ is positioned on a front surface of a first adhesive layer 40′ having relatively insufficient surface waviness according to a comparative example. For example, the first adhesive layer 40′ may include a pressure sensitive adhesive. FIG. 7 illustrates a display device in which a display panel 20 is positioned on a front surface of a first adhesive layer 40 having relatively excellent surface waviness according to an embodiment. For example, the first adhesive layer 40 may include a non-conductive film.

The first adhesive layer 40′ according to the comparative example of FIG. 6 may have a relatively low modulus. For a case in which the modulus is low, deformation may easily occur due to external forces. This may be expressed as having a high surface waviness value. In some aspects, it may be expressed as having poor surface waviness. Bending occurring in the first adhesive layer 40′ may cause bending of the display panel 20′. This is because the display panel 20′ is supported by the first adhesive layer 40′. Due to the bending of the first adhesive layer 40′ and the display panel 20′, distortion may occur depending on the position of the display panel 20′ where external light LP is incident.

FIG. 6 illustrates the first adhesive layer 40′ in which bending deformation occurs due to low modulus. Due to the bending of the first adhesive layer 40′, bending may also occur in the display panel 20′. The bending may occur in the third direction D3. External light LP incident on area A may be reflected from the first adhesive layer 40′ and the display panel 20′, respectively, to have an A1 optical path difference LPA1. External light LP incident on area B may be reflected from the first adhesive layer 40′ and the display panel 20′, respectively, to have a B1 optical path difference LPB1. In areas A and B, different optical path differences may occur due to the bent shapes of the display panel 20′ and the first adhesive layer 40′. That is, because different optical path differences occur depending on the position of the display panel 20′, a distorted image may be displayed in the electronic device.

FIG. 7 illustrates the first adhesive layer 40 in which bending deformation does not occur due to high modulus according to the embodiment. Because bending does not occur in the first adhesive layer 40, bending may not occur in the display panel 20 either. External light LP incident on area A may be reflected from the first adhesive layer 40 and the display panel 20, respectively, to have an A2 optical path difference LPA2. External light LP incident on area B may be reflected from the first adhesive layer 40 and the display panel 20, respectively, to have a B2 optical path difference LPB2. Because bending does not occur in the display panel 20 and the first adhesive layer 40 in areas A and B, the same optical path difference may occur. That is, because the same optical path difference occurs at different positions of the display panel 20, distortion of images in the electronic device may be prevented.

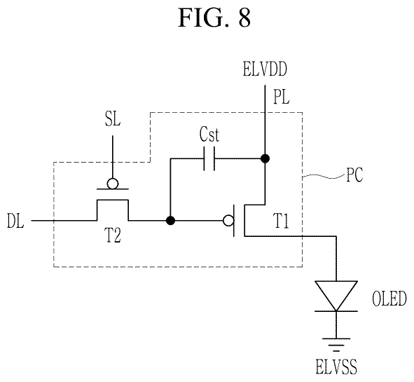

Hereinafter, pixels included in the display panel will be described with reference to FIGS. 8 and 9. FIG. 8 is an equivalent circuit diagram of any one pixel circuit included in the display panel. FIG. 9 is a cross-sectional view illustrating a portion of a display panel provided in the electronic device.

Referring to FIG. 8, the pixel circuit PC may include a driving transistor T1, a switching transistor T2, and a storage capacitor Cst. In some aspects, the pixel circuit PC may be electrically connected to an organic light emitting diode (OLED).

The switching transistor T2 may be connected to a data line DL and a scan line SL. The switching transistor T2 may transmit a data signal or data voltage input from the data line DL to the driving transistor T1 based on a scan signal or switching voltage input from the scan line SL.

The storage capacitor Cst is connected to the switching transistor T2 and the driving voltage line PL, and may store a voltage corresponding to a difference between a voltage received from the switching transistor T2 and a first power voltage ELVDD supplied to the driving voltage line PL.

The driving transistor T1 is connected to the driving voltage line PL and the storage capacitor Cst, and may control a driving current flowing from the driving voltage line PL to the organic light emitting diode (OLED) in response to a voltage value stored in the storage capacitor Cst. A counter electrode (e.g., cathode) of the organic light emitting diode (OLED) may receive a second power voltage ELVSS. The organic light emitting diode (OLED) may emit light having a predetermined luminance by the driving current.

In FIG. 8, a case where the pixel circuit PC includes two transistors and one storage capacitor has been described, but the present disclosure is not limited to this. For example, the pixel circuit PC may include three or more transistors. In some aspects, the pixel circuit PC may include two or more storage capacitors. As an example, the pixel circuit PC may include seven transistors and one storage capacitor. The number of transistors and storage capacitors may be variously changed according to the design of the pixel circuit PC.

In the above, it has been described that the electronic device includes an organic light emitting diode as a light emitting element, but the electronic device is not limited to this. In other examples, the electronic device may be a light emitting display device including an inorganic light emitting diode, that is, an inorganic light emitting display. In other examples, the electronic device may be a quantum dot light emitting display.

Referring to FIG. 9, the display panel 20 may include a substrate 100, a pixel circuit layer PCL, a display layer DISL, a thin film encapsulation layer TFE, and a touch sensing layer TSL.

The substrate 100 may have a multilayer structure including a base layer including a polymer resin and an inorganic layer. For example, the substrate 100 may include a base layer including a polymer resin and a barrier layer of an inorganic insulating layer. For example, the substrate 100 may include a first base layer 101, a first barrier layer 102, a second base layer 103, and a second barrier layer 104 which are sequentially stacked. The first base layer 101 and the second base layer 103 may include polyimide (PI), polyethersulfone (PES), polyarylate, polyetherimide (PEI), polyethylene naphthalate (PEN), polyethylene terephthalate (PET), polyphenylene sulfide (PPS), polycarbonate (PC), cellulose triacetate (TAC), and/or cellulose acetate propionate (CAP). The first barrier layer 102 and the second barrier layer 104 may include inorganic insulating materials such as, for example, silicon oxide, silicon oxynitride, and/or silicon nitride. Such a substrate 100 may have flexible characteristics.

A pixel circuit layer PCL may be disposed on the substrate 100. The pixel circuit layer PCL may include a pixel circuit PC including a transistor TFT and a storage capacitor Cst. In some aspects, the pixel circuit layer PCL may include a buffer layer 111, a first gate insulating layer 112, a second gate insulating layer 113, an interlayer insulating layer 114, a first insulating layer 115, and a second insulating layer 116 disposed below and/or above components of the pixel circuit PC.

The buffer layer 111 may reduce or block penetration of foreign substances, moisture, or external air from a lower portion of the substrate 100 and may provide a flat surface on the substrate 100. The buffer layer 111 may include inorganic insulating materials such as, for example, silicon oxide, silicon oxynitride, and/or silicon nitride, and may have a single layer or multilayer structure including the aforementioned materials.

The transistor TFT on the buffer layer 111 includes a semiconductor layer Act, and the semiconductor layer Act may include polysilicon. Alternatively, the semiconductor layer Act may include amorphous silicon, an oxide semiconductor, or an organic semiconductor, and the like. The semiconductor layer Act may include a channel region C and a drain region D and a source region S respectively disposed on both sides of the channel region C. The gate electrode GE may overlap the channel region C.

The gate electrode GE may include a low-resistance metal material. The gate electrode GE may include a conductive material including molybdenum (Mo), aluminum (Al), copper (Cu), titanium (Ti), and the like, and may be formed as a multilayer or single layer including the above materials.

The first gate insulating layer 112 between the semiconductor layer Act and the gate electrode GE may include inorganic insulating materials such as, for example, silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnOₓ). At this time, zinc oxide (ZnOₓ) may be zinc oxide (ZnO) and/or zinc peroxide (ZnO₂).

The second gate insulating layer 113 may be provided to cover the gate electrode GE. Similar to the first gate insulating layer 112, the second gate insulating layer 113 may include inorganic insulating materials such as, for example, silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnOₓ). At this time, zinc oxide (ZnOₓ) may be zinc oxide (ZnO) and/or zinc peroxide (ZnO₂).

An upper electrode Cst2 of the storage capacitor Cst may be disposed on an upper portion of the second gate insulating layer 113. The upper electrode Cst2 may overlap the gate electrode GE below it. The gate electrode GE and the upper electrode Cst2, with the second gate insulating layer 113 interposed between them, may overlap to form the storage capacitor Cst. That is, the gate electrode GE may function as a lower electrode Cst1 of the storage capacitor Cst.

As such, the storage capacitor Cst and the transistor TFT may be formed to overlap. In some examples, the storage capacitor Cst may be formed not to overlap the transistor TFT.

The upper electrode Cst2 may include aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), and/or copper (Cu), and may be a single layer or multiple layers of the aforementioned materials.

The interlayer insulating layer 114 may cover the upper electrode Cst2. The interlayer insulating layer 114 may include silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnOₓ). At this time, zinc oxide (ZnOₓ) may be zinc oxide (ZnO) and/or zinc peroxide (ZnO₂). The interlayer insulating layer 114 may be a single layer or multiple layers including the aforementioned inorganic insulating materials.

The drain electrode DE and the source electrode SE may be respectively positioned on the interlayer insulating layer 114. The drain electrode DE and the source electrode SE may be respectively connected to the drain region D and the source region S through contact holes of the insulating layers below them. The drain electrode DE and the source electrode SE may include materials with good conductivity. The drain electrode DE and the source electrode SE may include conductive materials including molybdenum (Mo), aluminum (Al), copper (Cu), and/or titanium (Ti), and may be formed as multiple layers or a single layer including the above materials. As an example, the drain electrode DE and the source electrode SE may have a multilayer structure of Ti/Al/Ti.

The first insulating layer 115 may cover the drain electrode DE and the source electrode SE. The first insulating layer 115 may include organic insulating materials such as, for example, general-purpose polymers like polymethylmethacrylate (PMMA) or polystyrene (PS), polymer derivatives having phenolic groups, acrylic polymers, imide polymers, aryl ether polymers, amide polymers, fluoropolymers, p-xylene-based polymers, vinyl alcohol-based polymers, and/or blends thereof.

The second insulating layer 116 may be disposed on the first insulating layer 115 and the contact metal CM. The second insulating layer 116 may include the same material as the first insulating layer 115, and may include organic insulating materials such as, for example, general-purpose polymers like polymethylmethacrylate (PMMA) or polystyrene (PS), polymer derivatives having phenolic groups, acrylic polymers, imide polymers, aryl ether polymers, amide polymers, fluorine polymers, p-xylene polymers, vinyl alcohol polymers, and/or blends thereof.

The display layer DISL may be disposed on the pixel circuit layer PCL having the aforementioned structure. The display layer DISL may include a light emitting element 200 and a pixel defining layer 120. The light emitting element 200 includes, for example, an organic light emitting diode (OLED), and the organic light emitting diode (OLED) may include a stacked structure of a first electrode 210, an intermediate layer 220, and a counter electrode 230. The organic light emitting diode (OLED) may emit, for example, red, green, or blue light, or may emit red, green, blue, or white light. The organic light emitting diode (OLED) emits light through a light emitting area, and the light emitting area may be defined as a light emitting pixel PX.

The first electrode 210 may be disposed on the second insulating layer 116. The first electrode 210 is connected to the contact metal CM disposed on the first insulating layer 115 through contact holes formed in the second insulating layer 116 and the first insulating layer 115, and may be electrically connected to the transistor TFT through the contact metal CM. Although this specification illustrates an example in which the transistor TFT and the first electrode 210 are connected through the contact metal CM, it is not limited to this, and the contact metal CM and the second insulating layer 116 may be omitted, and one electrode of the transistor TFT and the first electrode 210 may be directly connected.

The first electrode 210 may include conductive oxides such as, for example, indium tin oxide (ITO), indium zinc oxide (IZO), zinc oxide (ZnO), indium oxide (In₂O₃), indium gallium oxide (IGO), or aluminum zinc oxide (AZO). In other examples, the first electrode 210 may include a reflective layer including silver (Ag), magnesium (Mg), aluminum (Al), platinum (Pt), palladium (Pd), gold (Au), nickel (Ni), neodymium (Nd), iridium (Ir), chromium (Cr), or compounds thereof. In other examples, the first electrode 210 may further include a layer formed of ITO, IZO, ZnO, and/or In₂O₃ above/below the aforementioned reflective layer.

A pixel defining layer 120 having an opening 120OP exposing a central portion of the first electrode 210 is disposed on the first electrode 210. The pixel defining layer 120 may include organic insulating materials and/or inorganic insulating materials. The opening 120OP may define a light emitting area of light emitted from the light emitting element 200. For example, the size/width of the opening 120OP may correspond to the size/width of the light emitting area. Therefore, the size and/or width of the light emitting pixel PX may depend on the size and/or width of the opening 120OP of the corresponding pixel defining layer 120.

The intermediate layer 220 may include a light emitting layer 222 formed to correspond to the first electrode 210. The light emitting layer 222 may include a polymer or low molecular organic material which emits light of a predetermined color. Alternatively, the light emitting layer 222 may include an inorganic light emitting material or quantum dots.

A first functional layer 221 and a second functional layer 223 may be disposed below and above the light emitting layer 222, respectively. The first functional layer 221 may include, for example, a hole transport layer (HTL), or may include a hole transport layer and a hole injection layer (HIL). The second functional layer 223 is a component disposed above the light emitting layer 222 and may include an electron transport layer (ETL) and/or an electron injection layer (EIL). The first functional layer 221 and/or the second functional layer 223 may be a common layer formed to entirely cover the substrate 100, similar to the counter electrode 230 to be described later.

The counter electrode 230 is disposed on the first electrode 210 and may overlap the first electrode 210. The counter electrode 230 may be formed of a conductive material having a low work function. For example, the counter electrode 230 may include a transparent layer or semi-transparent layer including silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), and/or alloys thereof. Alternatively, the counter electrode 230 may further include a layer such as, for example, ITO, IZO, ZnO, and/or In2O3 on a transparent layer or semi-transparent layer including the aforementioned materials. The counter electrode 230 may be integrally formed to entirely cover the substrate 100.

The display panel 20 includes a plurality of light emitting elements 200, and the plurality of light emitting elements 200 may provide an image by emitting light through the light emitting pixels PX.

The thin film encapsulation layer TFE is disposed on the counter electrode 230 of the light emitting element 200 and may cover the light emitting elements 200 of the display layer DISL. The thin film encapsulation layer TFE may include at least one inorganic encapsulation layer and at least one organic encapsulation layer.

The first inorganic encapsulation layer 310 and the second inorganic encapsulation layer 330 may include one or more inorganic materials among aluminum oxide, titanium oxide, tantalum oxide, hafnium oxide, zinc oxide, silicon oxide, silicon nitride, and silicon oxynitride. The organic encapsulation layer 320 may include a polymer-based material. The polymer-based material may include acrylic resin, epoxy resin, and/or polyimide and polyethylene. As an example, the organic encapsulation layer 320 may include acrylate. The organic encapsulation layer 320 may be formed by curing a monomer or applying a polymer. The organic encapsulation layer 320 may have transparency.

A touch sensing layer TSL may be disposed on the thin film encapsulation layer TFE. As an example, as illustrated in FIG. 9, the touch sensing layer TSL may be directly formed on the thin film encapsulation layer TFE, and in this case, an adhesive layer may not be interposed between the touch sensing layer TSL and the thin film encapsulation layer TFE.

The touch sensing layer TSL may obtain coordinate information according to external input, for example, a touch event. The touch sensing layer TSL may include, for example, sensing electrodes and signal lines connected to the sensing electrodes. The touch sensing layer TSL may detect external input in a mutual cap method or a self-capacitance method.

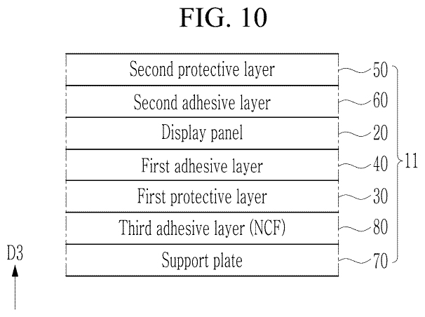

FIG. 10 is a view illustrating a stacked structure of a display device of an electronic device according to an embodiment. Description of components identical to the aforementioned components will be omitted.

The display device 11 may include a third adhesive layer 80 including a non-conductive film. The third adhesive layer 80 may be positioned between the first protective layer 30 and the support plate 70.

The first adhesive layer 40 may include at least one of an optically clear adhesive, an optically clear resin, a pressure sensitive adhesive, a thermally reactive adhesive, or a double-sided tape.

By including the non-conductive film in the third adhesive layer 80, buckling of the display panel 20 may be prevented. That is, by including the non-conductive film in the third adhesive layer 80, buckling of the display panel 20 may be prevented even for cases in which the first adhesive layer 40 does not include the non-conductive film. The third adhesive layer 80 is not in direct contact with the display panel 20. However, the high modulus and adhesive strength of the third adhesive layer 80 may prevent buckling of the display panel 20. For example, by using a non-conductive film having higher modulus and higher adhesive strength than using a pressure sensitive adhesive in the third adhesive layer 80, the overall rigidity of the display device 11 may be improved and excellent surface waviness may be maintained. The adhesive strength of the third adhesive layer 80 may be greater than the adhesive strength of the second adhesive layer 60.

The display device 11 may include the first adhesive layer 40 containing the non-conductive film and simultaneously include the third adhesive layer 80 containing the non-conductive film.

The third adhesive layer 80 may be in direct contact with the first protective layer 30. The first protective layer 30 may include a polymer member, metal, or glass. By the first protective layer 30 including metal or glass, the overall modulus of the display device included in the electronic device according to an embodiment may be improved, which may be advantageous in preventing buckling that may occur at a corner portion of the display panel 20.

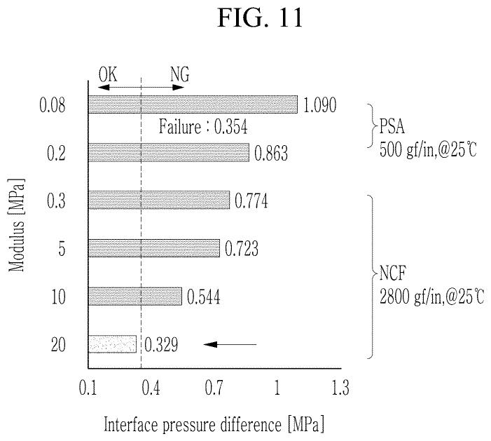

FIG. 11 is simulation data illustrating interface pressure differences according to materials of an adhesive layer.

FIG. 11 illustrates the interface pressure difference between the first adhesive layer and the display panel. The interface pressure difference may mean a difference in pressure occurring at an interface where two layers are in contact. The interface pressure difference affects structural strength and stability and may be related to defects at the interface or bonding of layers. The smaller the interface pressure difference between the first adhesive layer and the display panel, the more advantageous it may be to prevent delamination between the first adhesive layer and the display panel. In this simulation, a case where the interface pressure difference between the first adhesive layer and the display panel is 0.354 MPa or less is defined as an acceptable standard.

For a case in which the adhesive strength of the pressure sensitive adhesive (PSA) at 25° C. is 500 gf/in and the modulus is 0.08 MPa, the interface pressure difference between the first adhesive layer and the display panel is calculated to be 1.090 MPa. This does not satisfy the acceptable standard of this simulation.

For a case in which the adhesive strength of the pressure sensitive adhesive at 25° C. is 500 gf/in and the modulus is 0.2 MPa, the interface pressure difference between the first adhesive layer and the display panel is calculated to be 0.863 MPa. This does not satisfy the acceptable standard of this simulation.

For a case in which the adhesive strength of the non-conductive film (NCF) at 25° C. is 2800 gf/in and the modulus is 0.3 MPa, the interface pressure difference between the first adhesive layer and the display panel is calculated to be 0.774 MPa. This does not satisfy the acceptable standard of this simulation.

For a case in which the adhesive strength of the non-conductive film at 25° C. is 2800 gf/in and the modulus is 5 MPa, the interface pressure difference between the first adhesive layer and the display panel is calculated to be 0.723 MPa. This does not satisfy the acceptable standard of this simulation.

For a case in which the adhesive strength of the non-conductive film at 25° C. is 2800 gf/in and the modulus is 10 MPa, the interface pressure difference between the first adhesive layer and the display panel is calculated to be 0.544 MPa. This does not satisfy the acceptable standard of this simulation.

For a case in which the adhesive strength of the non-conductive film at 25° C. is 2800 gf/in and the modulus is 20 MPa, the interface pressure difference between the first adhesive layer and the display panel is calculated to be 0.329 MPa. This may satisfy the acceptable standard of this simulation.

In conclusion, a satisfactory interface pressure difference can be obtained for cases in which the adhesive strength is 2800 gf/in or more and the modulus is 20 MPa or more. In addition, embodiments of the present disclosure may include using a non-conductive film to obtain the target adhesive strength and modulus of the first adhesive layer.

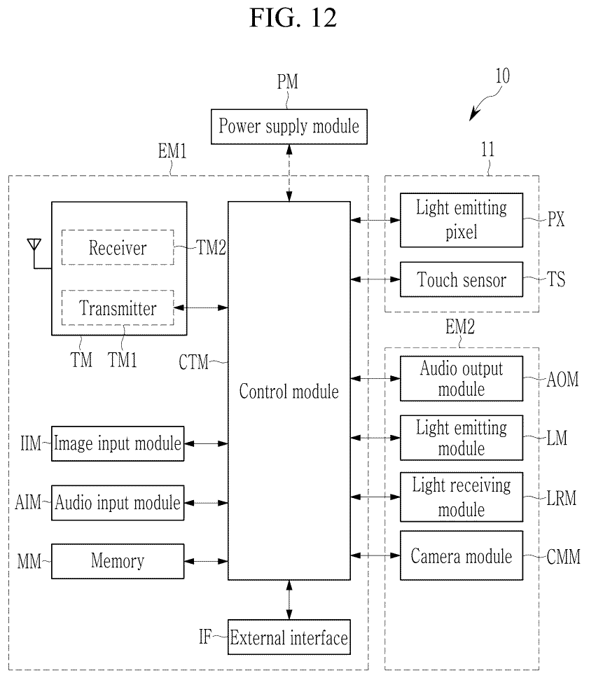

FIG. 12 is a block diagram of an electronic device according to an embodiment.

Referring to FIG. 12, an electronic device 10 according to an embodiment may include a display device 11, a power supply module PM, a first electronic module EM1, and a second electronic module EM2. The display device 11, the power supply module PM, the first electronic module EM1, and the second electronic module EM2 may be electrically connected to each other.

The display device 11 may include light emitting pixels PX and a touch sensor TS. The display device 11 may include light emitting pixels PX which are units for displaying images and may be visible to a user from the outside. The touch sensor TS may overlap the display panel and may detect external input.

The power supply module PM may supply power desirable for overall operation of the electronic device 10. The power supply module PM may include a battery module.

The first electronic module EM1 and the second electronic module EM2 may include various functional modules for operating the electronic device 10. The first electronic module EM1 may be directly mounted on a motherboard electrically connected to the display device 11 or may be mounted on a separate substrate and electrically connected to the motherboard through a connector or the like.

The first electronic module EM1 may include a control module CTM, a wireless communication module TM, an image input module IIM, an audio input module AIM, a memory MM, and an external interface IF. Some of the modules may not be mounted on the motherboard and may be electrically connected to the motherboard through a flexible printed circuit board connected to the motherboard.

The control module CTM may control overall operation of the electronic device 10. The control module CTM may be a microprocessor. For example, the control module CTM activates or deactivates the display device 11. The control module CTM may control other modules such as, for example, the image input module IIM or the audio input module AIM based on touch signals received from the display device 11.

The wireless communication module TM may transmit/receive wireless signals with other terminals using Bluetooth or Wi-Fi lines. The wireless communication module TM may transmit/receive voice signals using general communication lines. The wireless communication module TM includes a transmitter TM1 which modulates and transmits signals to be transmitted, and a receiver TM2 which demodulates received signals.

The image input module IIM may process image signals and convert them into image data displayable on the display device 11. The audio input module AIM may receive external audio signals through a microphone in recording mode, voice recognition mode, and the like, and convert them into electrical voice data.

The external interface IF may serve as an interface connected to external chargers, wired/wireless data ports, card sockets (e.g., memory cards, SIM/UIM cards), and the like.

The second electronic module EM2 may include an audio output module AOM, a light emitting module LM, a light receiving module LRM, and a camera module CMM, and at least some of these may be positioned on the rear surface of the display device 11 as optical elements. The optical elements may include the light emitting module LM, the light receiving module LRM, and the camera module CMM, and the like. In some aspects, the second electronic module EM2 may be directly mounted on a motherboard or mounted on a separate substrate and electrically connected to the display device 11 through a connector (not illustrated) or electrically connected to the first electronic module EM1.

The audio output module AOM may convert audio data received from the wireless communication module TM or audio data stored in the memory MM and output it externally.

The light emitting module LM may generate and output light. The light emitting module LM may output infrared light. For example, the light emitting module LM may include an LED element. For example, the light receiving module LRM may detect infrared light. The light receiving module LRM may be activated for cases in which infrared light above a predetermined level is detected. The light receiving module LRM may include a CMOS sensor. After infrared light generated by the light emitting module LM is output, it may be reflected by an external subject (e.g., a user's finger or face), and the reflected infrared light may be incident on the light receiving module LRM. The camera module CMM may capture external images.

An electronic device according to an embodiment may minimize electrical interference with the display panel by including a non-conductive film in the first adhesive layer positioned between the display panel and the first protective layer. In some aspects, for cases in which the first adhesive layer includes the non-conductive film, the adhesive strength and modulus of the first adhesive layer may be widely adjusted. Accordingly, embodiments of the present disclosure include adjusting the adhesive strength and modulus of the first adhesive layer such that buckling at corner portions of the display panel may be prevented or reduced.

Although the embodiments of the present disclosure have been described in detail above, the scope of rights of the present disclosure is not limited to thereto, and various modifications and improvements by those skilled in the art using the basic concept of the present disclosure defined in the following claims also belong to the scope of rights of the present disclosure.

What is claimed is:

1. An electronic device comprising:
a display panel comprising light emitting pixels;
a first protective layer positioned on a rear surface of the display panel; and
a first adhesive layer positioned between the display panel and the first protective layer,
wherein the first adhesive layer comprises a non-conductive film (NCF).

2. The electronic device of claim 1, wherein a modulus of the first adhesive layer is 20 MPa or greater.

3. The electronic device of claim 2, wherein an adhesive strength of the first adhesive layer is 2800 gf/in or greater.

4. The electronic device of claim 1, wherein the first protective layer comprises metal or glass.

5. The electronic device of claim 1, wherein the first protective layer is in direct contact with the first adhesive layer.

6. The electronic device of claim 1, further comprising a second protective layer positioned on a front surface of the display panel, wherein the front surface is opposite to the rear surface.

7. The electronic device of claim 6, further comprising a second adhesive layer positioned between the display panel and the second protective layer.

8. The electronic device of claim 7, wherein an adhesive strength of the first adhesive layer is greater than an adhesive strength of the second adhesive layer.

9. The electronic device of claim 1, wherein the display panel comprises:
a planar area; and
a curved area bent at a corner portion of the display panel,
wherein a display panel bending angle at which the display panel is bent in the curved area ranges from 45° to 85°.

10. The electronic device of claim 1, wherein the non-conductive film comprises epoxy, polyacrylate or urethane.

11. The electronic device of claim 1, further comprising a support plate positioned on a rear surface of the first protective layer.

12. An electronic device comprising:
a display panel comprising light emitting pixels;
a first protective layer positioned on a rear surface of the display panel;
a support plate positioned on a rear surface of the first protective layer; and
a third adhesive layer is positioned between the first protective layer and the support plate;
wherein the third adhesive layer comprises a non-conductive film (NCF).

13. The electronic device of claim 12, wherein a modulus of the third adhesive layer is 20 MPa or greater.

14. The electronic device of claim 13, wherein an adhesive strength of the third adhesive layer is 2800 gf/in or greater.

15. The electronic device of claim 12, wherein the first protective layer comprises metal or glass.

16. The electronic device of claim 12, wherein the first protective layer is in direct contact with the third adhesive layer.

17. The electronic device of claim 12, further comprising a second protective layer positioned on a front surface of the display panel, wherein the front surface is opposite to the rear surface.

18. The electronic device of claim 15, further comprising a second adhesive layer positioned between the display panel and the second protective layer.

19. The electronic device of claim 16, wherein an adhesive strength of the third adhesive layer is greater than an adhesive strength of the second adhesive layer.

20. The electronic device of claim 12, wherein the display panel comprises:
a planar area; and
a curved area bent at a corner portion of the display panel,
wherein a display panel bending angle at which the display panel is bent in the curved area ranges from 45° to 85°.
